(19) United States
(12) Patent Application Publication
(10) Pub. No.: US 2010/0084015 A1
(43) Pub. Date: Apr. 8, 2010

(54) THIN-FILM SOLAR CELL

(76) Inventors: Yung-Yuan CHANG, Houli Township (TW); Hui-Chu Lin, Houli Township (TW)

Correspondence Address: SINORICA, LLC, 2275 Research Blvd., Suite 500, ROCKVILLE, MD, 20850, US

(21) Appl. No.: 12/567,987

(22) Filed: Sep. 28, 2009

(30) Foreign Application Priority Data
Oct. 7, 2008 (TW) 097138510

(51) Int. Cl. H01L 31/00

(52) U.S. Cl. 136/256

(57) ABSTRACT

This invention discloses a thin-film solar cell, provided with a plurality of unit cells, comprising a substrate, a front electrode layer, an absorber layer and a back electrode layer stacked in such a sequence. The thin-film solar cell further includes at least a defect formed at least in the back electrode layer, and the defect has at least an isolation groove of a closed curve formed around the defect.

### BACKGROUND OF THE INVENTION

1. Technical Field

The present invention relates to a thin-film solar cell and, more particularly, to a thin-film solar cell having a defect surrounded by an isolation groove.

2. Description of Related Art

Generally, a thin-film solar cell is formed at least of a transparent substrate, a front electrode layer, an absorber layer, and a back electrode layer sequentially stacked up. During the manufacturing process of a thin-film solar cell, the foregoing layers are deposited and laser light cut so as to form a thin-film solar cell with a plurality of unit cells connected in series. While the layers are being laser light cut, any incomplete cut becomes a defect that may short-circuit the finished thin-film solar cell and thus lower the overall power generation efficiency thereof. To solve this problem, Japanese Patent Laid-Open Publication No. H8-037317 provides a method for detecting and removing a short-circuiting defect of a thin-film solar cell, wherein the method comprises determining the location of a defect in a back electrode layer by means of infrared thermal image measurement and then removing the defect with pulse laser light according to the location of the defect.

Nevertheless, the prior art cited above leaves much room for improvement in terms of defect removal from thin-film solar cells. More specifically, the prior art is directed essentially to the removal of a short-circuiting defect located in the back electrode layer of a thin-film solar cell. In practice, however, the defect of a thin-film solar cell may occur in places other than the back electrode layer, and the defect may cause problems other than a short circuit. As the absorber layer and the front electrode layer are also susceptible to defects of various forms during the manufacturing process of a thin-film solar cell, the above-cited prior art has its limitations in improving defect removal from thin-film solar cells. Therefore, it is a pressing issue for the related industry to provide more effective defect removal from thin-film solar cells than that furnished by the prior art.

### BRIEF SUMMARY OF THE INVENTION

To overcome the aforesaid shortcomings of the prior art, the present invention provides a thin-film solar cell embodying a specific way of defect removal such that a defect of the thin-film solar cell is surrounded by an isolation groove. The thin-film solar cell of the present invention, formed at least of a substrate, a front electrode layer, an absorber layer, and a back electrode layer stacked up sequentially, is characterized in that the thin-film solar cell further has at least one defect formed in the back electrode layer, and that the defect has at least an isolation groove of a closed-curve configuration formed around the defect.

Hence, a primary objective of the present invention is to provide a thin-film solar cell having a defect surrounded by an isolation groove, wherein the isolation groove is formed by removing a portion of a back electrode layer of the thin-film solar cell with one of ultraviolet laser light, green laser light, and infrared laser light.

A secondary objective of the present invention is to provide a thin-film solar cell having a defect surrounded by an isolation groove, wherein the isolation groove is formed by further removing a portion of an absorber layer of the thin-film solar cell with one of green laser light and infrared laser light.

Yet another objective of the present invention is to provide a thin-film solar cell having a defect surrounded by an isolation groove, wherein the isolation groove is formed by further removing a portion of a front electrode layer of the thin-film solar cell with infrared laser light.

### BRIEF DESCRIPTION OF THE SEVERAL VIEWS OF THE DRAWINGS

The structures and technical means adopted by the present invention to achieve the above and other objectives can be best understood by referring to the following detailed description of the preferred embodiments in conjunction with the accompanying drawings, in which:

FIG. 1A is a schematic top view of a first preferred embodiment of the present invention, showing steps of forming an isolation groove in a thin-film solar cell having a defect;

FIG. 1B is a schematic side sectional view of the first preferred embodiment taken along line A-A of FIG. 1A so as to show a first structure of the isolation groove;

FIG. 1C is another schematic side sectional view of the first preferred embodiment taken along line A-A of FIG. 1A so as to show a second structure of the isolation groove;

FIG. 2A is a schematic top view of a second preferred embodiment of the present invention, showing steps of forming a first isolation groove and a second isolation groove in a thin-film solar cell having a defect;

FIG. 2B is a schematic side sectional view of the second preferred embodiment taken along line B-B of FIG. 2A so as to show structures of the first and second isolation grooves;

FIG. 2C is another schematic side sectional view of the second preferred embodiment taken along line B-B of FIG. 2A so as to show other structures of the first and second isolation grooves;

FIG. 3A is a schematic top view of a third preferred embodiment of the present invention, showing steps of forming a first isolation groove, a second isolation groove, and a third isolation groove in a thin-film solar cell having a defect;

FIG. 3B is a schematic side sectional view of the third preferred embodiment taken along line C-C of FIG. 3A so as to show structures of the first, second, and third isolation grooves; and

FIG. 3C is another schematic side sectional view of the third preferred embodiment taken along line C-C of FIG. 3A so as to show other structures of the first, second, and third isolation grooves.

### DETAILED DESCRIPTION OF THE INVENTION

The present invention provides a thin-film solar cell, wherein the principle of photoelectric conversion from solar energy is well known to a person of ordinary skill in the art and therefore will not be detailed herein. Besides, it is to be understood that the drawings referred to in the following description are intended to demonstrate features of the present invention only schematically, so the drawings are not necessarily drawn to scale.

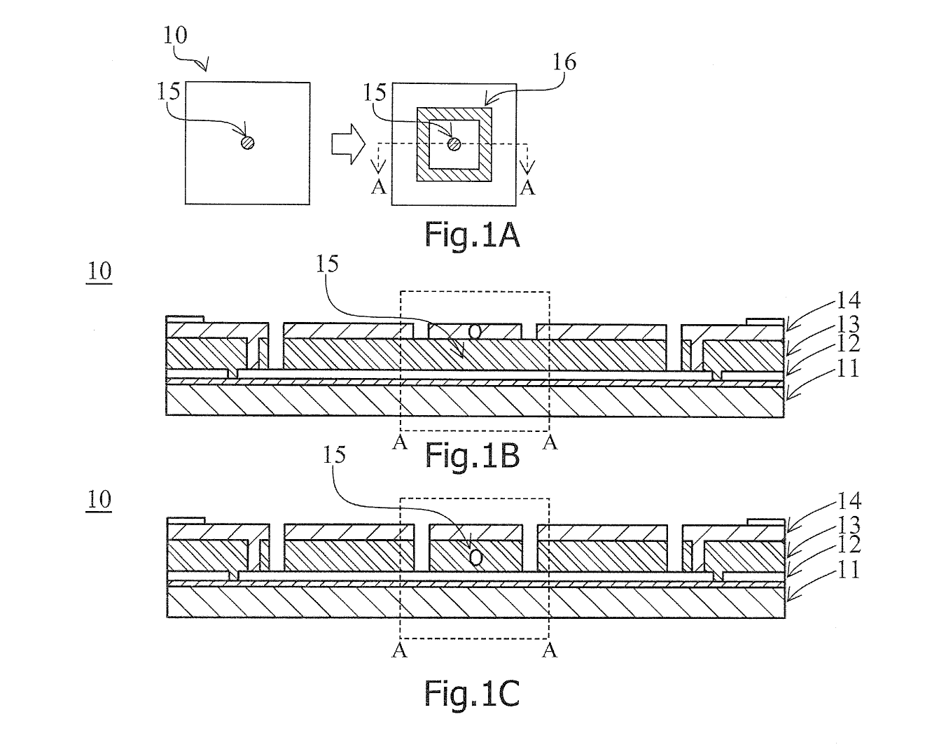

A first preferred embodiment of the present invention is shown in FIG 1A and FIG. 1B, which illustrate steps of forming an isolation groove in a thin-film solar cell having a defect. As shown in the drawings, a thin-film solar cell 10 is formed at least of a substrate 11, a front electrode layer 12, an absorber layer 13, and a back electrode layer 14 stacked up sequentially. The thin-film solar cell 10 further has at least one defect 15. At least one isolation groove 16 having a closed-curve configuration is formed around the defect 15 according to which layer of the thin-film solar cell 10 the defect 15 is in.

FIG. 1B is a sectional view taken along line A-A of FIG 1A and shows a first structure of the isolation groove 16 formed in the thin-film solar cell 10 of the first preferred embodiment. The isolation groove 16 in FIG. 1B is formed when the defect 15 is located in the back electrode layer 14. More specifically, the back electrode layer 14 is partially removed with ultraviolet laser light, green laser light, or infrared laser light along a closed curve centered around the defect 15. Thus, the isolation groove 16 having a closed-curve configuration is formed in the back electrode layer 14 to isolate the defect 15 of the thin-film solar cell 10.

Please refer to FIG. 1C, which is another sectional view taken along line A-A of FIG. 1A, for a second structure of the isolation groove 16 formed in the thin-film solar cell 10 of the first preferred embodiment. The isolation groove 16 in FIG. 1C is formed when the defect 15 is located in the absorber layer 13. More specifically, the back electrode layer 14 and the absorber layer 13 are partially removed with green laser light or infrared laser light along a closed curve centered around the defect 15. Thus, the isolation groove 16 having the second structure that extends from the back electrode layer 14 through the absorber layer 13 is formed to isolate the defect 15 of the thin-film solar cell 10, thereby increasing overall power generation efficiency of the thin-film solar cell 10.

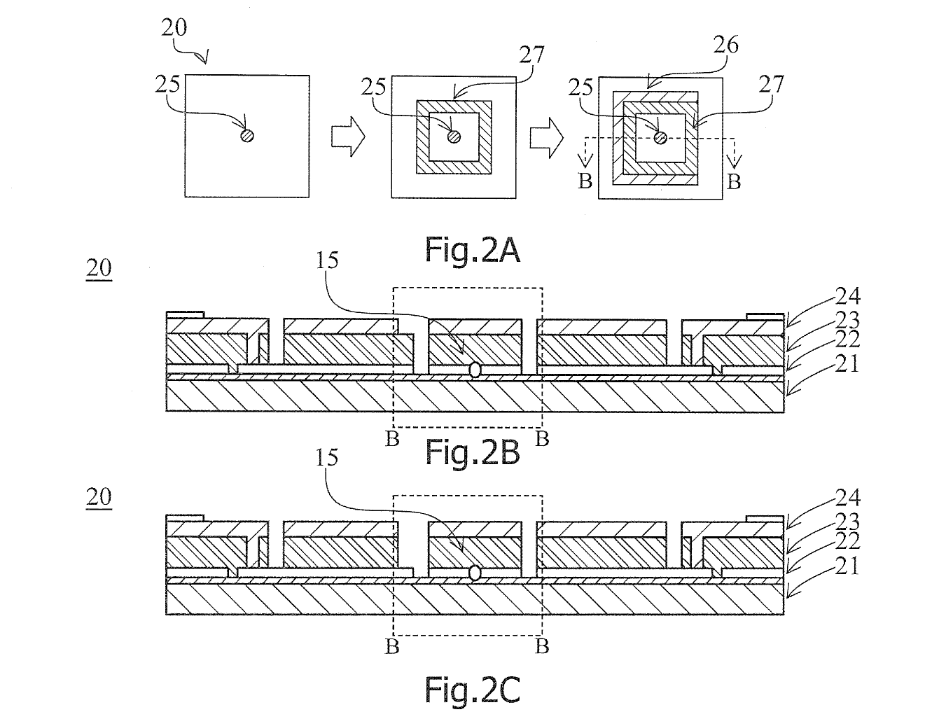

A second preferred embodiment of the present invention is shown in FIG. 2A and FIG. 2B, which illustrate steps of forming isolation grooves in a thin-film solar cell having a defect. As shown in the drawings, a thin-film solar cell 20 is formed at least of a substrate 21, a front electrode layer 22, an absorber layer 23, and a back electrode layer 24 sequentially stacked up. The thin-film solar cell 20 further has at least one defect 25. A second isolation groove 27 and a first isolation groove 26 are formed successively around the defect 25 according to which layer of the thin-film solar cell 20 the defect 25 is in. The second isolation groove 27 has a closed-curve configuration.

FIG. 2B is a sectional view taken along line B-B of FIG. 2A and shows structures of the first isolation groove 26 and the second isolation groove 27 formed in the thin-film solar cell 20 of the second preferred embodiment. When the defect 25 is located in the front electrode layer 22, the back electrode layer 24, the absorber layer 23, and the front electrode layer 22 are partially removed with infrared laser light along a closed curve centered around the defect 25, thereby forming the second isolation groove 27. Following that, only the back electrode layer 24 is partially removed with ultraviolet laser light, green laser light, or infrared laser light along a path which runs outside and along the second isolation groove 27 and is centered around the defect 25, thereby forming the first isolation groove 26. The second isolation groove 27 is adjacent to the first isolation groove 26. Moreover, the second isolation groove 27 has a groove width smaller than or equal to that of the first isolation groove 26. Consequently, the defect 25 of the thin-film solar cell 20 is isolated to increase overall power generation efficiency of the thin-film solar cell 20.

Please refer to FIG. 2C, which is another sectional view taken along line B-B of FIG. 2A, for other structures of the first and second isolation grooves 26, 27 formed in the thin-film solar cell 20 of the second preferred embodiment. In this case, formation of the second isolation groove 27 also corresponds to the defect 25 in the front electrode layer 22. To begin with, the back electrode layer 24, the absorber layer 23, and the front electrode layer 22 are partially removed with infrared laser light along a closed curve centered around the defect 25, thereby forming the second isolation groove 27. Next, green or infrared laser light output is directed along a path which runs outside and along the second isolation groove 27 and is centered around the defect 25, so as to partially remove not only the back electrode layer 24 but also the absorber layer 23 as the laser light output further extends from the back electrode layer 24 through the absorber layer 23, thereby forming the first isolation groove 26. The second isolation groove 27 is adjacent to the first isolation groove 26. Moreover, a groove width of the second isolation groove 27 in the absorber layer 23 is smaller than or equal to a groove width of the first isolation groove 26 in the back electrode layer 24. As a result, the defect 25 of the thin-film solar cell 20 is isolated to increase overall power generation efficiency of the thin-film solar cell 20.

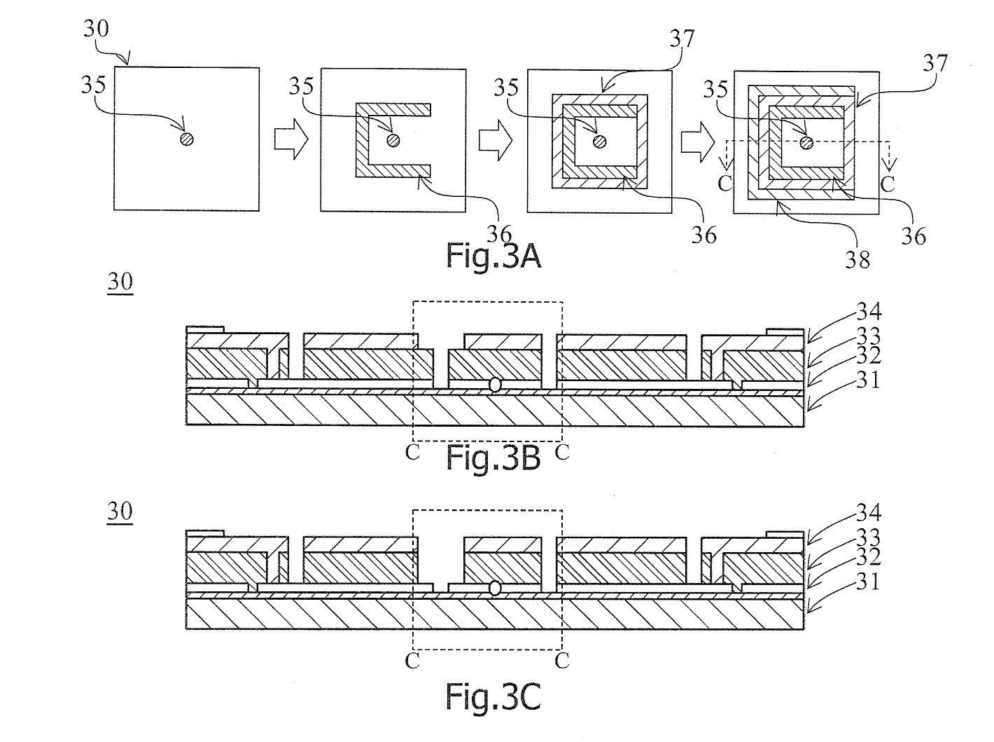

A third preferred embodiment of the present invention is shown in FIG. 3A and FIG. 3B, which illustrate steps of forming isolation grooves in a thin-film solar cell having a defect. As shown in the drawings, a thin-film solar cell 30 is formed at least of a substrate 31, a front electrode layer 32, an absorber layer 33, and a back electrode layer 34 sequentially stacked up. The thin-film solar cell 30 further has at least one defect 35. A first isolation groove 36, a second isolation groove 37, and a third isolation groove 38 are formed successively around the defect 35 according to which layer of the thin-film solar cell 30 the defect 35 is in. The second isolation groove 37 has a closed-curve configuration.

FIG. 3B is a sectional view taken along line C-C of FIG. 3A and shows structures of the first, second and third isolation grooves 36, 37, 38 formed in the thin-film solar cell 30 of the third preferred embodiment. When the defect 35 is in the front electrode layer 32, the back electrode layer 34 is partially removed with ultraviolet laser light, green laser light, or infrared laser light along a path centered around the defect 35, thereby forming the first isolation groove 36. Next, the back electrode layer 34, the absorber layer 33, and the front electrode layer 32 are partially removed with infrared laser light along a closed curve which surrounds the first isolation groove 36 and is centered around the defect 35, thereby forming the second isolation groove 37 having a closed-curve configuration. Finally, the back electrode layer 34 is partially removed with ultraviolet laser light, green laser light, or infrared laser light along a path centered around the defect 35, thereby forming the third isolation groove 38. The third isolation groove 38 is adjacent to the second isolation groove 37, and the second isolation groove 37 is adjacent to the first isolation groove 36. Furthermore, the third isolation groove 38 has a groove width smaller than or equal to that of the second isolation groove 37, and the groove width of the second isolation groove 37 is smaller than or equal to that of the first isolation groove 36. Consequently, the defect 35 of the thin-film solar cell 30 is isolated to increase overall power generation efficiency of the thin-film solar cell 30.

Please refer to FIG. 3C, which is another sectional view taken along line C-C of FIG. 3A, for another structure of the first, second and third isolation grooves 36, 37, 38 formed in the thin-film solar cell 30 of the third preferred embodiment. To begin with, the back electrode layer 34 and the absorber layer 33 are partially removed with green laser light or infrared laser light along a path centered around the defect 35, thereby forming the first isolation groove 36. Following that, infrared laser light output is directed along a closed curve which surrounds the first isolation groove 36 and is also centered around the defect 35, so as to partially remove not only the back electrode layer 34 and the absorber layer 33 but also the the front electrode layer 32 as the infrared laser light output extends the front electrode layer 32 from the back electrode layer 34 through the absorber layer 33, thereby forming the second isolation groove 37. Finally, the back electrode layer 34 and the absorber layer 33 are partially removed with green laser light or infrared laser light along a path which runs outside and along the second isolation groove 37 and is centered around the defect 35, thereby forming the third isolation groove 38. The third isolation groove 38 is adjacent to the second isolation groove 37, and the second isolation groove 37 is adjacent to the first isolation groove 36. Moreover, the third isolation groove 38 has a groove width smaller than or equal to that of the second isolation groove 37, and the groove width of the second isolation groove 37 is smaller than or equal to that of the first isolation groove 36. Consequently, the defect 35 of the thin-film solar cell 30 is isolated to increase overall power generation efficiency of the thin-film solar cell 30.

In the first, second, and third preferred embodiments of the present invention, the groove width of each isolation groove ranges from 0.001 μm to 100000 μm, and the closed-curve configurations of those isolation grooves having the same can be any one of a rectangle, a triangle, a polygon, a circle, an ellipse, or an island shape.

The present invention is described herein by reference to the preferred embodiments, and it is understood that the embodiments are not intended to limit the scope of the present invention. Moreover, as the contents disclosed herein should be readily understood and can be implemented by a person skilled in the art, all equivalent changes or modifications which do not depart from the spirit of the present invention should be encompassed by the appended claims.

What is claimed is:

1. A thin-film solar cell, formed of a plurality of unit cells, comprising a substrate, a front electrode layer, an absorber layer, and a back electrode layer sequentially stacked up, wherein the thin-film solar cell has at least a defect formed in the back electrode, the defect having at least an isolation groove of a closed-curve configuration formed around the defect.

2. The thin-film solar cell of claim 1, wherein the isolation groove is formed by removing a portion of the back electrode layer with one of ultraviolet laser light, green laser light, and infrared laser light.

3. The thin-film solar cell of claim 1, wherein the isolation groove is formed by removing a portion of the back electrode layer and the absorber layer with one of ultraviolet laser light, green laser light, and infrared laser light.

4. The thin-film solar cell of claim 1, wherein the isolation groove has a groove width ranging from 0.001 μm to 100000 μm.

5. The thin-film solar cell of claim 1, wherein the closed-curve configuration of the isolation groove is selected from the group consisting of a rectangle, a triangle, a polygon, a circle, an ellipse, and an island shape.

6. A thin-film solar cell, formed of a plurality of unit cells, comprising a substrate, a front electrode layer, an absorber layer, and a back electrode layer sequentially stacked up, wherein the thin-film solar cell has at least a defect formed in the absorber layer, the defect having at least an isolation groove of a closed-curve configuration formed around the defect.

7. The thin-film solar cell of claim 6, wherein the isolation groove includes a first isolation groove that is formed by removing a portion of the back electrode layer with one of ultraviolet laser light, green laser light, and infrared laser light.

8. The thin-film solar cell of claim 7, wherein the isolation groove further includes a second isolation groove that is formed by removing a portion of the absorber layer with one of green laser light and infrared laser light.

9. The thin-film solar cell of claim 7, wherein the first isolation groove has a groove width ranging from 0.001 μm to 100000 μm.

10. The thin-film solar cell of claim 8, wherein the second isolation groove has a groove width ranging from 0.001 μm to 100000 μm.

11. The thin-film solar cell of claim 8, wherein the second isolation groove has a groove width less than that of the first isolation groove.

12. The thin-film solar cell of claim 8, wherein the second isolation groove has a groove width equal to that of the first isolation groove.

13. The thin-film solar cell of claim 8, wherein the closed-curve configuration of the first and second isolation grooves is selected from the group consisting of a rectangle, a triangle, a polygon, a circle, an ellipse, and an island shape.

14. A thin-film solar cell, formed of a plurality of unit cells, comprising a substrate, a front electrode layer, an absorber layer, and a back electrode layer sequentially stacked up, wherein the thin-film solar cell has at least a defect formed in the front electrode layer, the defect having at least an isolation groove of a closed-curve configuration formed around the defect.

15. The thin-film solar cell of claim 14, wherein the isolation groove includes a first isolation groove that is formed by removing a portion of the back electrode layer with one of ultraviolet laser light, green laser light, and infrared laser light.

16. The thin-film solar cell of claim 15, wherein the isolation groove further includes a second isolation groove that is formed by removing a portion of the absorber layer with one of green laser light and infrared laser light.

17. The thin-film solar cell of claim 16, wherein the isolation groove further includes a third isolation groove that is formed by removing a portion of the front electrode layer with infrared laser light.

18. The thin-film solar cell of claim 15, wherein the first, second and third isolation grooves have a groove width ranging from 0.001 μm to 100000 μm, respectively.

19. The thin-film solar cell of claim 17, wherein the second isolation groove has a groove width less than or equal to that of the first isolation groove, and the third isolation groove has a groove width less than or equal to that of the second isolation groove.

20. The thin-film solar cell of claim 17, wherein the closed-curve configuration of the first, second and third isolation grooves is selected from the group consisting of a rectangle, a triangle, a polygon, a circle, an ellipse, and an island shape.
